(19) United States
(12) Patent Application Publication
(10) Pub. No.: US 2012/0019264 A1
(43) Pub. Date: Jan. 26, 2012

(54) MULTI PURPOSE CAPACITIVE SENSOR

(76) Inventor: Lars Ake Wern, Stockholm (SE)

(21) Appl. No.: 13/144,108

(22) PCT Filed: Jan. 4, 2010
(86) PCT No.: PCT/SE2010/000001

§ 371 Date: Sep. 22, 2011

(30) Foreign Application Priority Data
Jan. 13, 2009 (SE) 0900033-2

(51) Int. Cl. G01R 27/26

(52) U.S. Cl. 324/676

(57) ABSTRACT

A multi purpose capacitive sensor which is suitable for indicating close proximity of a person to a surface along a large-size truck as well as along a medium-size painting. A voltage measuring device is provided with a signal ground connected to a first pole of an oscillating voltage source that has a second pole connected to earth and that is connected to an input of the voltage measuring device via a voltage divider with a capacitive series link arranged between the input and earth and a shunt link arranged between the input and the signal ground. The signal ground is connected to electrically conductive means extended along the surface and the oscillating voltage source is connected to earth via a second voltage divider in which a capacitive series link is arranged between the earth and the second pole.

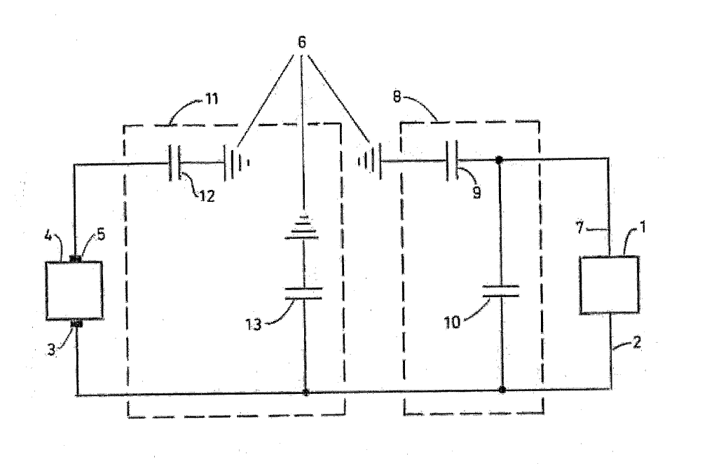

### TECHNICAL FIELD

The invention relates to a multi purpose capacitive sensor which is suitable for indicating close proximity of a person to a surface along a large-size truck as well as along a medium-size painting and in which a voltage measuring device is provided with a signal ground connected to a first pole of an oscillating voltage source that has a second pole connected to earth and that is connected to an input of the voltage measuring device via a voltage divider with a capacitive series link arranged between said input and earth and a shunt link arranged between said input and said signal ground.

### BACKGROUND OF THE INVENTION

The Swedish Patent No. 355 719 discloses a capacitive sensor capable of sensing the immediate proximity of a person's finger to an electrical conductor extended along a wall. It represents a first step towards developing a multi purpose device which is suitable for indicating close proximity of a person to a surface along an object such as a truck or a painting. In the known sensor, a voltage measuring device is provided with a signal ground connected to a first pole of an AC power line that has a second pole connected to earth and that is connected to an input of the voltage measuring device via a voltage divider with a capacitive series link arranged between said input and earth and a shunt link arranged between said input and said signal ground. While it is obvious that the AC power line could be replaced by a battery powered oscillating voltage source and that the man skilled in the art also could improve the voltage measuring device, the connection to earth of the voltage source creates a problem. The known sensor is not sensitive unless the impedance of this connection is considerably lower than the capacitive impedance to earth presented by the object at which close proximity is to be indicated. This is easy to arrange for the entire surface of trucks only when they are parked, and a wired connection to earth limits the use of the known sensor for protecting paintings in museums.

### SUMMARY OF THE INVENTION

The multi purpose capacitive sensor of the invention is suitable for indicating close proximity of a person to a surface along a large-size truck as well as along a medium-size painting. It comprises a voltage measuring device provided with a signal ground connected to a first pole of an oscillating voltage source that has a second pole connected to earth and that is connected to an input of the voltage measuring device via a voltage divider with a capacitive series link arranged between said input and earth and a shunt link arranged between said input and the signal ground. According to the invention as defined in the appended claims, a solution is found to the problem of providing capacitive sensors with a wireless connection to earth in applications that include vehicles as well as artworks.

### BRIEF DESCRIPTION OF THE DRAWING

The multi purpose capacitive sensor according to the invention will now be described with reference to the drawing which shows a block diagram of a preferred embodiment.

### PREFERRED EMBODIMENT

In the drawing, a block diagram shows a multi purpose capacitive sensor that is suitable for indicating close proximity of a person to a surface along a large-size truck as well as along a medium-size painting. A voltage measuring device 1 is provided with a signal ground 2 connected to a first pole 3 of an oscillating voltage source 4 that has a second pole 5 connected to earth 6 and that is connected to an input 7 of the voltage measuring device 1 via a voltage divider 8 with a capacitive series link 9 arranged between earth 6 and the input 7 and a capacitive shunt link 10 arranged between signal ground 2 and the input 7. According to the invention, the signal ground 2 is connected to electrically conductive means extended along said surface and the oscillating voltage source 4 is connected to earth 6 via a second voltage divider 11 in which a capacitive series link 12 is arranged between earth 6 and the second pole 5 and has an impedance of at least the same order of magnitude as the impedance of a capacitive shunt link 13 provided by the capacitance between the signal ground 2 and earth 6.

In the preferred embodiment of the invention, the repetition frequency and the voltage amplitude of the oscillation voltage source 4 can have an order of magnitude of 10 kHz and 10V, respectively. Using in known manner a microprocessor and an analog-to-digital converter to detect quite small changes in the voltage amplitude at the input 7, the voltage measuring device 1 is capable of indicating close proximity to a surface along a big truck as well as along a precious painting. The voltage divider 11 makes it possible to counteract an influence from humidity in the environment and the same goes for the voltage divider 8 where the series link 9 and the shunt link 10 are provided by one and the same electric conductor that is connected to the input 7 of the voltage measuring device 1 and presents mainly free air capacitance with respect to earth 6 and to signal ground 2, respectively.

An electric conductor connected to the second pole 5 of the voltage source 4 and extended between said surface and earth 6 can provide the capacitive series link 12 of the second voltage divider 11. While the distance to said electrically conductive means is not critical for the electric conductor that results in the capacitive series link 12, it should for the electric conductor providing the capacitive series link 9 and the capacitive shunt link 10 be chosen with as much free air space as possible in the application. The same goes for the distance between said electric conductors, for example when said surface pertains to an artwork where the capacitive shunt link 13 is conveniently provided by an electrically conductive foil arranged below said surface and connected to the signal ground 2. The electric conductor that determines the capacitive series link 12 could be located quite close to the foil. However, it should not be close to the second conductor that determines the capacitive series link 9 and also the capacitive link 10 and that therefore is preferably located at a distance from the foil. In a battery powered embodiment for a stand-alone wall in a room where a painting is provided with a plastic back plate that has on one side said electrically conductive foil arranged behind the painting and on an opposite side facing the wall the electric conductor providing the capacitive series link 12, the capacitive sensor could work with the latter conductor simply extended along the periphery of the plate. While proximity of a person to the painting would be indicated by the voltage measuring device 1 as a decrease in voltage, the immediate proximity of a person on the other side of the wall could be indicated as an increase in voltage that should simply be ignored in this application. However, a combined use of these proximity indications makes it in a door application for the described plate embodiment of the capacitive sensor of the invention possible to tell whether people come or leave.

In a vehicle application where said electrically conductive means pertains to a metal chassis and wheels provide an insulation with respect to earth, the capacitive shunt link 13 of the second voltage divider 11 is determined by the capacitance between earth and the chassis. Insulated electric cables can be used as said conductors and the one providing the capacitive series link 12 can be fastened in immediate proximity to the chassis. The magnitude of its shunt capacitance between the signal ground 2 and the output 5 of the oscillating voltage source 4 is not a problem. However, the electric cable that provides the capacitive series link 9 and the capacitive shunt link 10 should not be positioned unnecessarily close to the chassis. For example, it could be fastened below such a plastic surface close to earth that is common today for vehicles in their front. An approaching object in this area is indicated by the voltage measuring device 1 as an increased voltage, but close proximity to the chassis or to metal components that are connected to the chassis is instead indicated by a decreased voltage. These indications can be used to generate an alert message to the driver and also to trigger a local alarm or a central alarm.

The man skilled in the art can make many obvious improvements of the preferred embodiment as described above, for example by implementing so-called spread spectrum modulation in the oscillating voltage source 4 with a corresponding demodulation in the voltage measuring device 1 so as to counteract possible electromagnetic interference when two artworks or two vehicles have adjacent surfaces and both of them are provided with the capacitive sensor of the invention as defined by the appended claims.

1. A multi purpose capacitive sensor which is suitable for indicating close proximity of a person to a surface along a large-size truck as well as along a medium-size painting and in which a voltage measuring device (1) is provided with a signal ground (2) connected to a first pole (3) of an oscillating voltage source (4) that has a second pole (5) connected to earth (6) and that is connected to an input (7) of the voltage measuring device via a voltage divider (8) with a capacitive series link (9) arranged between said input and earth and a shunt link (10) arranged between said input and said signal ground, characterized thereby that said signal ground is connected to electrically conductive means extended along said surface and that said oscillating voltage source is connected to earth via a second voltage divider (11) in which a capacitive series link (12) is arranged between earth and said second pole and has an impedance of at least the same order of magnitude as the impedance of a capacitive shunt link (13) provided by the capacitance between said signal ground and earth.

2. A multi purpose capacitive sensor according to claim 1, characterized thereby that said capacitive series link of said second voltage divider is provided by an electric conductor connected to said second pole of said voltage source and extended between said electrically conductive means and earth.

3. A multi purpose capacitive sensor according to claim 1, characterized thereby that said electrically conductive means pertains to a chassis of a vehicle.

4. A multi purpose capacitive sensor according to claim 2, characterized thereby that said electrically conductive means pertains to a chassis of a vehicle.
